(19) United States
(12) Patent Application Publication
(10) Pub. No.: US 2023/0308780 A1
(43) Pub. Date: Sep. 28, 2023

(54) IMAGING DEVICE, AND ELECTRONIC INSTRUMENT COMPRISING IMAGING DEVICE

(71) Applicant: Rosnes Corporation, Kyoto (JP)

(72) Inventor: Takumi YAMAGUCHI, Kyoto (JP)

(21) Appl. No.: 18/041,518

(22) PCT Filed: Aug. 19, 2021
(86) PCT No.: PCT/JP2021/030362

§ 371 Date: Feb. 13, 2023

(30) Foreign Application Priority Data
Aug. 21, 2020 (JP) 2020-140340

(51) Int. Cl. H04N 25/702; H04N 25/77; H04N 25/703; H01L 27/146

(52) U.S. Cl. CPC H04N 25/702; H04N 25/77; H04N 25/703; H01L 27/14636

(57) ABSTRACT

Provided is an imaging device and an electronic apparatus including the imaging device capable of realizing high-speed driving of a drive wiring and a signal line of a pixel and realizing miniaturization, high resolution, and high sensitivity. An imaging device having a pixel arrangement in which rectangular pixels whose horizontal pixel dimension is longer than a vertical pixel dimension are arranged by being moved in a horizontal direction every other row by a shift dimension of ½ of a horizontal pixel dimension.

### TECHNICAL FIELD

The present invention relates to an imaging device and, more particularly, to an imaging device periodically arranged in a matrix.

The present invention also relates to an electronic apparatus including the imaging device.

### BACKGROUND ART

In recent years, in a CMOS image sensor which is a mainstream of an imaging device used in a camera, realizing high-speed driving of a drive wiring of a pixel, and miniaturization, high resolution, and high sensitivity is required.

FIG. 20 is a diagram of a pixel of a conventional general CMOS image sensor. In particular, in order to realize miniaturization, high resolution, and high sensitivity of the CMOS image sensor, a pixel 1 has a simple structure including a light receiving unit 2, a reading unit 3, and an output unit 4.

A signal charge generated in the light receiving unit 2 of the pixel 1 is transferred to the output unit 4 by applying a pulse voltage of a horizontal drive wiring 5 to the reading unit 3. The charge transferred to the output unit 4 is converted into a voltage and read out from a vertical signal line 6.

The shape indicating the boundary region of the pixel 1 is generally a square, and in the case of FIG. 20, a vertical pixel dimension 7 and a horizontal pixel dimension 8 have the same value.

FIG. 21 is an arrangement diagram of a conventional CMOS image sensor in which square pixels are arranged in a matrix. The pixels 1 are arranged in a matrix at a pitch of the horizontal pixel dimension 8 of the pixels in the horizontal axis (H) direction of the rows and at a pitch of the vertical pixel dimension 7 in the vertical axis (V) direction of the columns.

A signal based on the charge of the light receiving unit 2 of the pixel 1 in each column (Y, Y+1, Y+2, Y+3) in an X row is read out from the output unit 4 of each pixel to the outside of the CMOS sensor through the vertical signal line 6. Similarly, the signals of the pixels in each row are read out in the order of X+1, X+2, and X+3.

FIG. 22 shows operation waveforms of a conventional pixel. The operation waveforms are drive waveforms related to operations of the light receiving unit 2, the reading unit 3, the output unit 4, the horizontal drive wiring 5, and the vertical signal line 6 in FIG. 20.

In FIG. 20, only one horizontal drive wiring 5 is shown for simplification of the drawing, but there are actually a plurality of drive wirings 5 for driving pixels. FIG. 22 shows pulses of two drive wirings 5 necessary for reading out signals. unit 4.

T1 of a reset pulse (5-1) is a pulse of the drive wiring for resetting the output unit 4.

T2 and T5 of a read pulse (5-2) are pulses of the drive wiring applied to the reading unit 3.

The drive wiring 5 of FIG. 20 is a wiring connected to the reading unit 3, and indicates a wiring of the read pulse (5-2). In FIG. 20, the drive wiring to which the reset pulse (5-1) is applied actually exists, but is omitted because it may complicate the drawing.

FIG. 22 shows waveforms of the reset pulse (5-1), the read pulse (5-2), and the vertical signal line 6 connected to the output unit 4.

When T1 of the reset pulse (5-1) is applied to the output unit 4, the output unit 4 is reset to the initial state, and the vertical signal line 6 has a reset potential (V3). The reset potential (V3) is continued for the time of T3 until the read pulse (5-2) is applied.

When T2 of the read pulse (5-2) is applied to the reading unit 3, the signal charge of the light receiving unit 2 is read out to the output unit 4. When the output unit is a floating diffusion (FD) type amplifier, the signal charge of the light receiving unit 2 is read out to the FD.

At this time, the potential of the vertical signal line 6 changes to a signal potential (V4) in accordance with the amount of signal charge.

The signal potential (V4) is again continued for the time of T4 until T5 is applied again to the reset pulse (5-1).

Since the duration time T3 of the reset potential (V3) and the duration time T4 of the signal potential (V4) of the vertical signal line 6 are analog potentials, an AD conversion processing from analog to digital is performed after they are taken out from the vertical signal line 6.

In order to improve the signal-to-noise ratio SN of the AD conversion processing, the duration time T3 of the reset potential (V3) and the duration time T4 of the signal potential (V4) need to be as long as possible.

In particular, it is necessary to avoid the influence of jump noise transmitted from T1 and T5 of the reset pulse (5-1) and T2 of the read pulse (5-2) to the vertical signal line 6.

Therefore, it is considered that the duration time T3 and the duration time T4 are preferably 10 times or more the pulse width of the pulses T1, T5, or T2.

Therefore, in order to increase the operating frequency of the CMOS image sensor by minimizing the entire signal outputting period (T5), it is necessary to lengthen T3 and T4 and shorten T1, T2 and T5.

As described above, it is required that the duration time T3 of the reset potential (V3) and the duration time T4 of the signal potential (V4) are low-frequency outputs for as long a time as possible and T1 and T5 of the reset pulse (5-1) and T2 of the read pulse (5-2) are high-frequency pulses for a short time. Therefore, the horizontal drive wiring 5 needs to be designed to withstand high-speed driving as compared with the vertical signal line 6.

FIG. 23 shows a pixel obtained by rotating the square pixel by 45 degrees.

This structure is proposed in Patent Document 1, Patent Document 2, and Patent Document 3 as a means for realizing miniaturization and high resolution of the CMOS image sensor. The rotation pixel 9 shown in FIG. 23 has a structure in which the pixel 1 shown in FIG. 20 is simply rotated by 45 degrees.

FIG. 24 is an arrangement diagram of a CMOS image sensor in which the pixels rotated by 45 degrees are arranged in a staggered manner. Such an arrangement is referred to as a honeycomb arrangement in Patent Document 1, Patent Document 2, and Patent Document 3.

This structure is a method of simply rotating the pixel by 45 degrees, and this structure is a conventionally well-known method in a pixel of a CCD or CMOS image sensor.

Since the rotation pixel 9 of FIG. 24 is square,
a horizontal resolution 10 is
(the horizontal pixel dimension 8 of the pixel 1 of FIG. 20) ×√2÷2.

A vertical resolution 11 of FIG. 24 is
(the vertical pixel dimension 7 of the pixel 1 of FIG. 20) ×√2÷2.

Therefore, it can be seen that the horizontal and vertical resolutions can be improved by arranging the pixels in a staggered manner.

On the other hand, in the rotation pixels 9 arranged in a staggered manner as shown in FIG. 24, the drive wiring 5 needs to be bent like mountains and valleys, and the distance of the drive wiring 5 is longer than that in the case where the drive wiring 5 is arranged in a straight line.

For this reason, while the drive wiring 5 of the pixel 1 of FIG. 20 is in a straight line, the drive wiring 5 of the rotation pixels 9 arranged in a staggered manner has a long distance, and thus, a problem arises in that high-speed driving is difficult.

In particular, when the imaging region of the CMOS image sensor is large and the total extension distance of the drive wiring 5 is long, the problem becomes remarkable.

In particular, in the case of a large number of pixels with a large number of pixels in the horizontal direction, the total extension distance of the drive wiring 5 is further increased, and thus, the wiring resistance is increased. In addition, when the pixel is miniaturized, the wiring width is narrowed, and thus, the wiring resistance is further increased. As described above, with respect to the increase in the number of horizontal pixels and the miniaturization of the pixels, there arises a problem that the driving speed of the drive wiring 5 is limited to a low speed in the rotation pixels 9 arranged in a staggered manner.

In the state of the arrangement shown in FIG. 24, the width of the drive wiring 5 is increased to reduce the wiring resistance, thereby achieving high-speed driving, however, as an adverse effect of increasing the wiring width, the light receiving unit 2 becomes extremely small, and a problem of a decrease in the sensitivity of the light receiving unit occurs.

In FIG. 24, the vertical signal line 6 is intentionally not shown on the drawing. Since the vertical signal line 6 transmits a low-frequency signal, even if the wiring is bent, there is no problem because the influence of the wiring length is small, and thus the vertical signal line 6 is not illustrated.

FIG. 25 is a diagram of a pixel of a conventional charge-holding-type CMOS image sensor based on global shutter. In a pixel 12 based on global shutter, a reading unit 13 and a signal holding unit 14 are additionally provided between the light receiving unit 2 and the transfer unit 3 in FIG. 20.

In this case, in addition to the drive wiring 5 in the horizontal direction, a reading unit wiring 15 and a signal holding unit wiring 16 are added in the horizontal direction.

When the pixels 12 based on global shutter are arranged in a staggered manner as in FIG. 24, three wirings of the drive wiring 5, the reading unit wiring 15, and the signal holding unit wiring 16 are bent like mountains and valleys, and the distances of all three high-speed wirings are increased.

Therefore, in the pixel 12 of the CMOS image sensor based on global shutter which requires an increase in the speed, the number of horizontal drive wirings is larger than that of the pixel 1 of FIG. 20. Thus, when the pixels 12 are arranged in a honeycomb arrangement which is in a staggered manner, as shown in FIG. 24, there arises a problem that it is impossible to bend a plurality of wirings like mountains and valleys and it is impossible to form a plurality of drive wirings.

Although not illustrated in FIG. 25, in a distance sensor of a ToF (Time of Flight) CMOS image sensor, there is a plurality of signal holding units 14, and the number of horizontal drive wirings is further larger than that of a CMOS image sensor based on global shutter.

Therefore, in the ToF CMOS image sensor, there arises a problem that a honeycomb arrangement which is in a staggered manner cannot be realized.

FIG. 26-1 is a diagram illustrating an aspect ratio of horizontal:vertical=4:3 of a television image.

FIG. 26-2 is a diagram illustrating an aspect ratio of horizontal:vertical=16:9 of a high-resolution television image.

FIG. 26-3 is a diagram illustrating an aspect ratio of horizontal:vertical=12:5 of a movie image.

As shown in FIG. 26-1, the aspect ratio of a television image 17 is 4:3 in the early age of television, but in recent years, as shown in FIG. 26-2, the aspect ratio of a high-resolution television image 18 is 16:9 and the horizontal distance becomes longer.

Further, as shown in FIG. 26-3, the aspect ratio of a movie image 19 is 12:5, and the horizontal distance is further increased.

Therefore, the horizontal drive wiring 5 of the pixel 1 of FIG. 20 or the pixel 12 of FIG. 25 of the CMOS image sensor becomes longer.

Further, in order to realize the high-resolution television image 18 and the movie image 19, it is necessary to miniaturize the CMOS image sensor and increase the resolution of the CMOS image sensor.

As described above, in the recent CMOS image sensor for the high-resolution television image 18 and the movie image 19, it is necessary to increase the distance of the horizontal drive wiring 5, to miniaturize the CMOS image sensor and to increase the resolution of the CMOS image sensor.

Therefore, it is difficult to perform the honeycomb arrangement of the conventional CMOS image sensor. Further, the CMOS image sensor based on global shutter and the ToF CMOS image sensor cannot be arranged in a honeycomb arrangement.

### PRIOR ART DOCUMENTS

### Patent Documents

Patent Document 1: Japanese Patent Laid-open Publication No. 2006-41799

Patent Document 2: Japanese Patent Laid-open Publication No. 2009-296276

Patent Document 3: Japanese Patent Laid-open Publication No. H06-77450

### SUMMARY OF THE INVENTION

### Problems to be Solved by the Invention

However, as described above, in the CMOS image sensor, when the pixels are arranged in a honeycomb arrangement, the drive wiring and the signal line become long, and thus it is difficult to increase the speed, and it is also difficult to realize miniaturization, increase the resolution, and increase the sensitivity.

In addition, when an attempt is made to increase the speed by widening the drive wiring and the signal line, the area of the light receiving unit becomes extremely small, and a problem of a decrease in the sensitivity of the light receiving unit occurs.

In particular, in a CMOS image sensor based on global shutter or a ToF CMOS image sensor, since the number of horizontal drive wirings is larger than that in a conventional CMOS image sensor, it is more difficult to design the horizontal drive wiring when the pixels are arranged in a honeycomb arrangement, and it is impossible to realize miniaturization, high resolution, and high sensitivity of the CMOS image sensor.

In addition, the aspect ratio of the high-resolution television image is horizontal:vertical=16:9, and the aspect ratio of the movie image is horizontal:vertical=12:5, and the horizontal ratio is large.

Therefore, in the CMOS image sensor for the high-resolution television image 18 or the movie image 19, since the horizontal drive wiring is further longer than that of the conventional CMOS image sensor for television images, it is further difficult to design the horizontal drive wiring, and it is impossible to realize miniaturization and high resolution of the CMOS image sensor.

The object of the present invention is to provide an imaging device and an electronic apparatus including the imaging device capable of realizing high-speed driving of a drive wiring and a signal line of a pixel and realizing miniaturization, high resolution, and high sensitivity.

### Solutions to the Problems

An imaging device has pixels, each of the pixels including:

a light receiving unit that photoelectrically converts an incident light to generate a signal charge;

an output unit that detects the signal charge of the light receiving unit; and

a drive wiring that operates the output unit,

wherein

in an imaging region where the pixels are periodically arranged in a matrix

at a pitch of a horizontal pixel dimension in a row direction and

at a pitch of a vertical pixel dimension in a column direction,

an arrangement of the pixels in an X row and an (X+2) row is an arrangement in which the pixels in an (X+1) row and an (X+3) row are moved in the row direction by a shift dimension smaller than the horizontal pixel dimension, or

an arrangement of the pixels in a Y column and a (Y+2) column is an arrangement in which the pixels in a (Y+1) column and a (Y+3) column are moved in the column direction by a shift dimension smaller than the vertical pixel dimension.

When the arrangement of the pixels in the X row and the (X+2) row is the arrangement in which the pixels in the (X+1) row and the (X+3) row are moved in the row direction by the shift dimension smaller than the horizontal pixel dimension,

the drive wiring of the pixel and the drive wiring of the adjacent pixel have at least one wiring connected horizontally in a same row, or

when the arrangement of the pixels in the Y column and the (Y+2) column is the arrangement in which the pixels in the (Y+1) column and the (Y+3) column are moved in the column direction by the shift dimension smaller than the vertical pixel dimension,

the drive wiring of the pixel and the drive wiring of an adjacent pixel have at least one wiring connected vertically in a same column.

A signal line for outputting a signal from the output unit of the pixel and the signal line of the pixel adjacent in the column direction are connected in the column direction.

The imaging device has an imaging region which is rotated and arranged within a range of less than 360 degrees.

When the arrangement of the pixels in the X row and the (X+2) row is the arrangement in which the pixels in the (X+1) row and the (X+3) row are moved in the row direction by the shift dimension smaller than the horizontal pixel dimension,

the shift dimension is ½ of the horizontal pixel dimension, or

when the arrangement of the pixels in the Y column and the (Y+2) column is the arrangement in which the pixels in the (Y+1) column and the (Y+3) column are moved in the column direction by the shift dimension smaller than the vertical pixel dimension,

the shift dimension is ½ of the vertical pixel dimension.

When the arrangement of the pixels in the X row and the (X+2) row is the arrangement in which the pixels in the (X+1) row and the (X+3) row are moved in the row direction by the shift dimension smaller than the horizontal pixel dimension,

the vertical pixel dimension is smaller than the horizontal pixel dimension, or

when the arrangement of the pixels in the Y column and the (Y+2) column is the arrangement in which the pixels in the (Y+1) column and the (Y+3) column are moved in the column direction by the shift dimension smaller than the vertical pixel dimension,

the horizontal pixel dimension is smaller than the vertical pixel dimension.

When the arrangement of the pixels in the X row and the (X+2) row is the arrangement in which the pixels in the (X+1) row and the (X+3) row are moved in the row direction by the shift dimension smaller than the horizontal pixel dimension,

the vertical pixel dimension is ½ of the horizontal pixel dimension, or when an arrangement of pixels in the Y column and the (Y+2) column is the arrangement in which pixels in the (Y+1) column and the (Y+3) column are moved in the column direction by the shift dimension smaller than the vertical pixel dimension,

the horizontal pixel dimension is ½ of the vertical pixel dimension.

A total row dimension of the pixels arranged in the row direction at the pitch of the horizontal pixel dimension is larger than a total column dimension of the pixels arranged in the column direction at the pitch of the vertical pixel dimension.

In the imaging region,

micro-lenses having an area center of gravity are arranged in a staggered manner on the light receiving unit.

A voltage applied to the drive wiring has

a pulse width of 5 microseconds or less or

a sine wave of 5 microseconds or less.

The pixels are global shutter pixels having a signal holding unit for holding a signal of the light receiving unit, or

Time of Flight (ToF) pixels having a plurality of the signal holding units.

The pixel is a back side illumination type pixel in which the drive wiring is formed on a surface side of a semiconductor, and

the light receiving unit is formed on a back side of the semiconductor, and is thus a so-called Back Side Illumination (BSI) type pixel.

The light receiving units of the back side illumination type pixels are in a staggered arrangement.

In the back side illumination type pixel,

of surface circuit units in which the drive wiring is formed on the surface side of the semiconductor,

the arrangement of the surface circuit units of the X row and the (X+2) row is an arrangement in which the surface circuit units of the (X+1) row and the (X+3) row are moved in the row direction by the shift dimension smaller than the horizontal pixel dimension of the surface circuit units, or

the arrangement of the surface circuit units of the Y column and the (Y+2) column is an arrangement in which the surface circuit units of the (Y+1) column and the (Y+3) column are moved in the column direction by the shift dimension smaller than the vertical pixel dimension of the surface circuit units.

### Effects of the Invention

According to the present invention, it is possible to provide an imaging device and an electronic apparatus including the imaging device capable of realizing high-speed driving of a drive wiring and a signal line of a pixel and realizing miniaturization, high resolution, and high sensitivity.

### BRIEF DESCRIPTION OF THE DRAWINGS

FIG. 1 shows a pixel arrangement in which pixels whose horizontal pixel dimension and vertical pixel dimension are the same are moved in a horizontal direction every other row by a shift dimension of ½ of the horizontal pixel dimension.

FIG. 2 shows a rectangular pixel having a vertical pixel dimension smaller than the horizontal pixel dimension.

FIG. 3 shows a pixel arrangement in which rectangular pixels whose vertical pixel dimension is smaller than the horizontal pixel dimension are moved in the horizontal direction every other row by the shift dimension of ½ of the horizontal pixel dimension.

FIG. 4 shows a rectangular pixel having a vertical pixel dimension of ½ of a horizontal pixel dimension.

FIG. 5 shows a pixel arrangement in which rectangular pixels having a vertical pixel dimension of ½ of a horizontal pixel dimension are moved in the horizontal direction every other row by a shift dimension of ½ of the horizontal pixel dimension.

FIG. 6 shows a pixel arrangement in which micro-lenses are formed on rectangular pixels having a vertical pixel dimension of ½ of a horizontal pixel dimension and the micro-lenses are arranged in a staggered manner.

FIG. 7 shows a pixel arrangement in which pixels whose horizontal pixel dimension and vertical pixel dimension are the same are arranged by being moved in a vertical direction every other column by a shift dimension of ½ of the vertical pixel dimension.

FIG. 8 shows a pixel arrangement in which rectangular pixels whose vertical pixel dimension is longer than horizontal pixel dimension are arranged by being moved in a vertical direction every other column by a shift dimension of ½ of the vertical pixel dimension.

FIG. 9 shows a pixel arrangement in which pixels whose drive wirings are arranged in a vertical direction are arranged by being moved in the vertical direction every other column by a shift dimension of ½ of the vertical pixel dimension.

FIG. 10 shows a side view of a back side illumination type pixel and top and bottom views of the back side illumination type pixel.

FIG. 11 shows a pixel arrangement in which, in a back side illumination type pixel, back side light receiving units are arranged by being moved in a horizontal direction every other row by a shift dimension of ½ of a horizontal pixel dimension.

FIG. 12 shows a pixel arrangement in which, in a back side illumination type pixel, surface circuit units are arranged by being moved in a horizontal direction every other row by a shift dimension of ½ of a horizontal pixel dimension.

FIG. 13 shows a pixel arrangement in which back side illumination type pixels are arranged by being moved in a horizontal direction every other row by a shift dimension of ½ of a horizontal pixel dimension.

FIG. 14 shows a pixel arrangement in which back side illumination type pixels are arranged by being moved in a vertical direction every other column by a shift dimension of ½ of a vertical pixel dimension.

FIG. 15 shows a pixel arrangement in which surface circuit units of back side illumination type pixels whose vertical pixel dimension is smaller than horizontal pixel dimension are arranged by being moved in the horizontal direction every other row by a shift dimension of ½ of the horizontal pixel dimension.

FIG. 16 shows a pixel arrangement in which back side light receiving units of back side illumination type pixels whose vertical pixel dimension is smaller than horizontal pixel dimension are arranged by being moved in the horizontal direction every other row by a shift dimension of ½ of the horizontal pixel dimension.

FIG. 17 shows a pixel arrangement in which back side illumination type pixels which have surface circuit units and back side light receiving units and have a vertical pixel dimension which is smaller than a horizontal pixel dimension are arranged by being moved in the horizontal direction every other row by a shift dimension of ½ of the horizontal pixel dimension.

FIG. 18 is a back side illumination type pixel arrangement diagram in which back side light receiving units are arranged in a staggered manner.

FIG. 19 is an arrangement diagram in which a rectangular surface circuit unit and a back side light receiving unit with a staggered arrangement are overlapped with each other.

FIG. 20 is a diagram of a pixel of a conventional general CMOS image sensor.

FIG. 21 is an arrangement diagram of a conventional CMOS image sensor in which square pixels are arranged in a matrix.

FIG. 22 shows operation waveforms of a conventional pixel.

FIG. 23 shows a pixel obtained by rotating a quadrangular pixel by 45 degrees.

FIG. 24 is an arrangement diagram of a CMOS image sensor in which pixels rotated by 45 degrees are arranged in a staggered manner.

FIG. 25 is a diagram of a pixel of a conventional charge-holding-type CMOS image sensor based on global shutter.

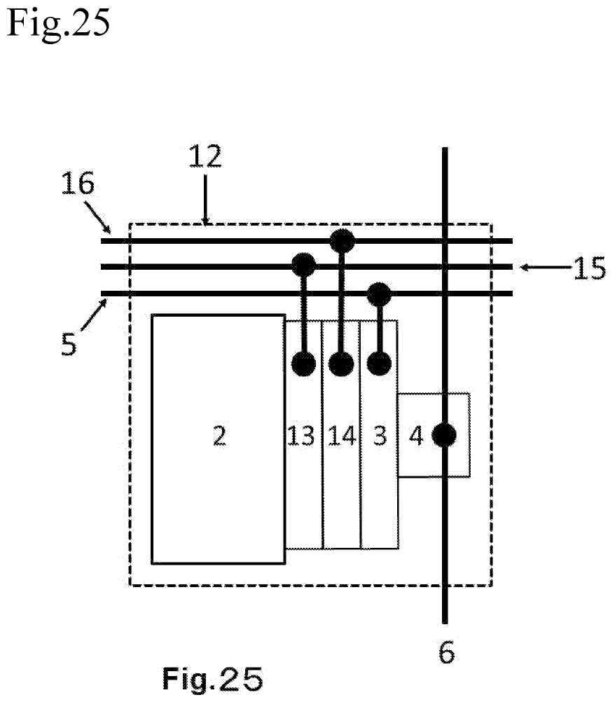

FIG. 26 is a diagram showing an aspect ratio of horizontal:vertical=4:3 of a television image, an aspect ratio of horizontal:vertical=16:9 of a high-resolution television image, and an aspect ratio of horizontal:vertical=12:5 of a movie image.

### EMBODIMENT OF THE INVENTION

Here provides an imaging device capable of increasing the speed of a drive wiring and a signal line of a CMOS image sensor, and realizing miniaturization, high resolution, and high sensitivity of the CMOS image sensor. An embodiment of the present invention will be described below with reference to the accompanying drawings.

### Embodiment

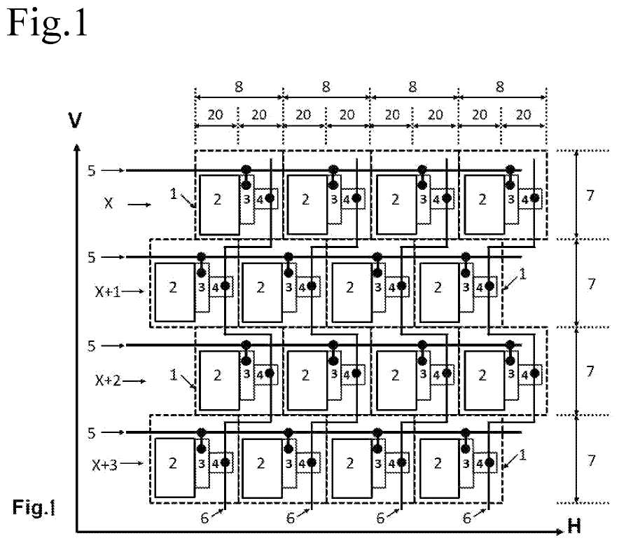

FIG. 1 shows a pixel arrangement in which pixels whose horizontal pixel dimension and vertical pixel dimension are the same are moved in a horizontal direction every other row by a shift dimension of ½ of the horizontal pixel dimension.

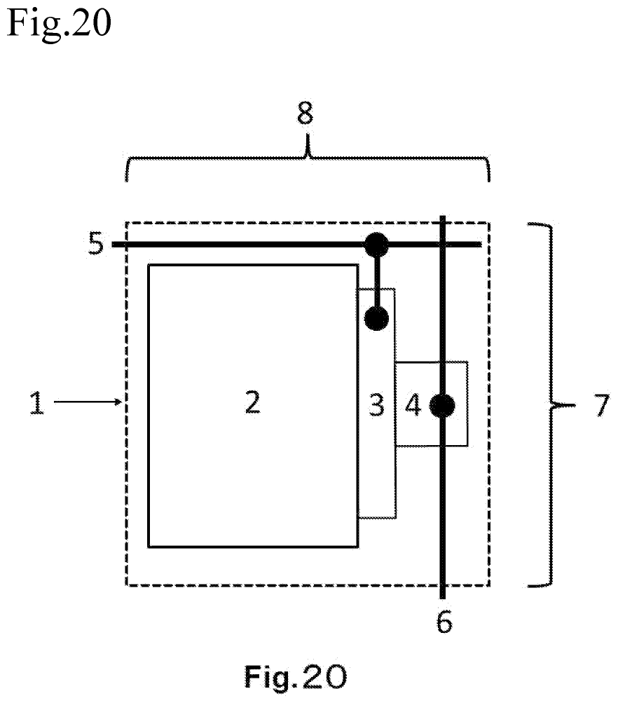

FIG. 1 is a diagram in which the pixels 1 of FIG. 20 are moved every other row by a shift dimension of ½ of the horizontal pixel dimension 8, and shows a pixel arrangement in which the horizontal resolution is improved as compared with FIG. 20.

The arrangement of the pixels of the X row and the (X+2) row is an arrangement in which the pixels of the (X+1) row and the (X+3) row are moved in the row direction by the shift dimension of ½ of the horizontal pixel dimension 8.

In this case, since the light receiving unit 2 in the horizontal direction has a horizontal resolution dimension 20 which is half of the horizontal pixel dimension 8, the horizontal resolution is improved to double the conventional resolution.

The vertical resolution of FIG. 1 is the same as that of FIG. 20 because the light receiving units 2 in the vertical direction are repeated with the same vertical pixel dimension 7 as that of FIG. 20.

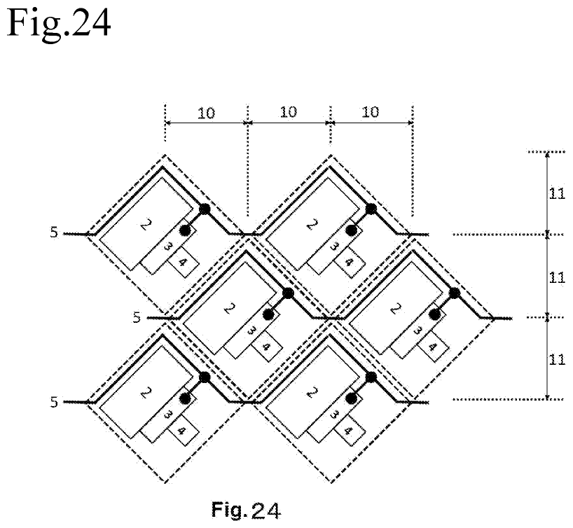

In FIG. 1, since the pixel 1 is shifted only in the horizontal direction, the drive wiring 5 of the pixel 1 is not largely bent as in the staggered arrangement of FIG. 24. Therefore, high-speed driving of the drive wiring 5 can be realized.

As described above, by moving the pixels 1 every other row in the horizontal direction by the shift dimension of ½ of the horizontal pixel dimension 8, there is an advantage that higher horizontal resolution can be realized while higher speed driving of the drive wiring 5 can be realized.

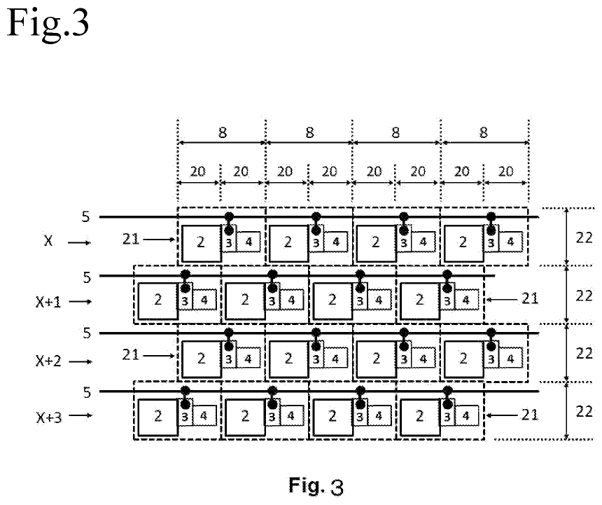

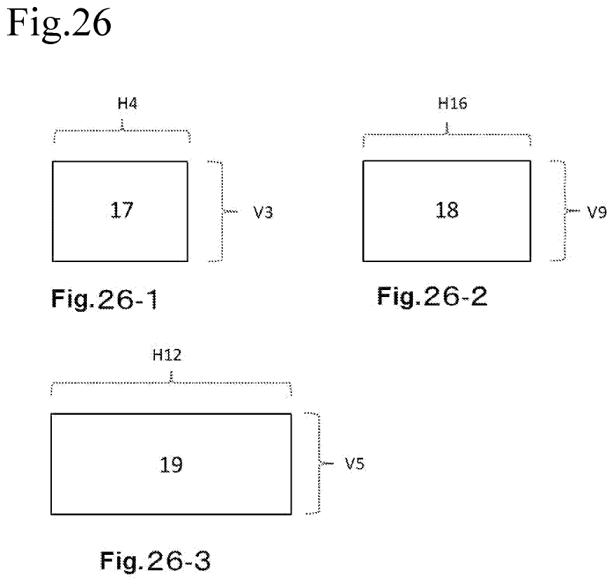

In addition, when a CMOS image sensor having a large horizontal ratio such as the aspect ratio of horizontal:vertical=12:5 of the movie image of FIG. 26-3 is manufactured by the arrangement method of FIG. 1, it is possible to simultaneously realize high horizontal resolution and high-speed driving of the drive wiring 5.

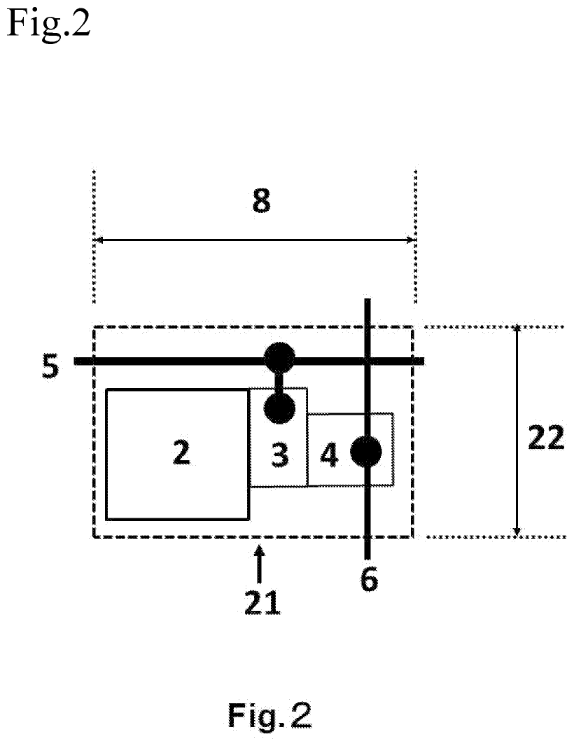

FIG. 2 shows a rectangular pixel having a vertical pixel dimension smaller than the horizontal pixel dimension. In FIG. 1, in the arrangement of the pixels in the X row and the (X+2) row, the horizontal resolution dimension 20 can be reduced by moving the pixels in the (X+1) row and the (X+3) row in the row direction by the shift dimension of ½ of the horizontal pixel dimension 8, but the vertical resolution cannot be improved.

In a horizontally long rectangular pixel 21 of FIG. 2, a vertical pixel dimension 22 is smaller than the horizontal pixel dimension 8. Thus, the vertical resolution can be improved.

FIG. 3 shows a pixel arrangement in which rectangular pixels whose vertical pixel dimension is smaller than the horizontal pixel dimension are moved in the horizontal direction every other row by the shift dimension of ½ of the horizontal pixel dimension.

In FIG. 3, in the arrangement of the pixels in the X row and the (X+2) row, the horizontal resolution dimension 20 can be reduced by moving the pixels in the (X+1) row and the (X+3) row in the row direction by the shift dimension of ½ of the horizontal pixel dimension 8, and further, by reducing the vertical pixel dimension 22, the vertical resolution dimension can also be reduced.

As described above, in FIG. 3, the horizontal resolution and the vertical resolution can be improved at the same time, and miniaturization and high resolution of the CMOS image sensor can be realized.

Further, in FIG. 3, similarly to FIG. 1, since the horizontally long rectangular pixel 21 is only shifted in the horizontal direction, the drive wiring 5 of the horizontally long rectangular pixel 21 is not largely bent as in the staggered arrangement of FIG. 24. Therefore, since the drive wiring 5 can be wired in a straight line, high-speed driving can be realized.

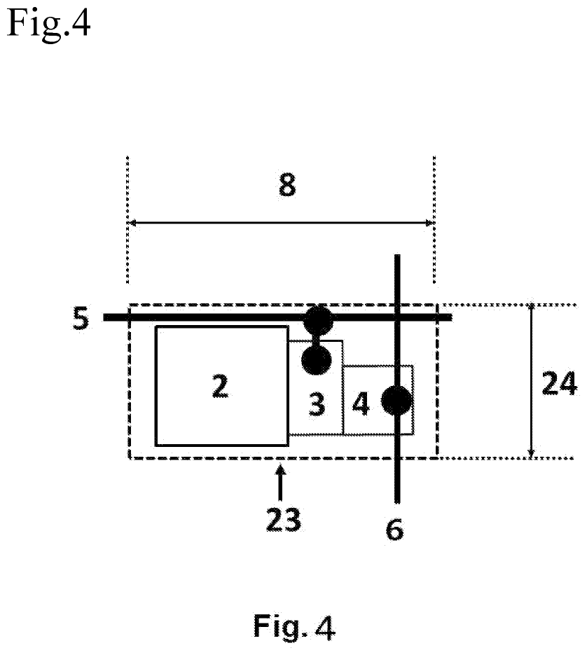

FIG. 4 shows a rectangular pixel having a vertical pixel dimension of ½ of a horizontal pixel dimension.

A high-resolution pixel 23 of FIG. 4 is a rectangular pixel having a vertical pixel dimension 24 of ½ of the horizontal pixel dimension 8. As a result, the vertical resolution dimension and the horizontal resolution dimension can be made equal to each other by an arrangement similar to that shown in FIG. 1.

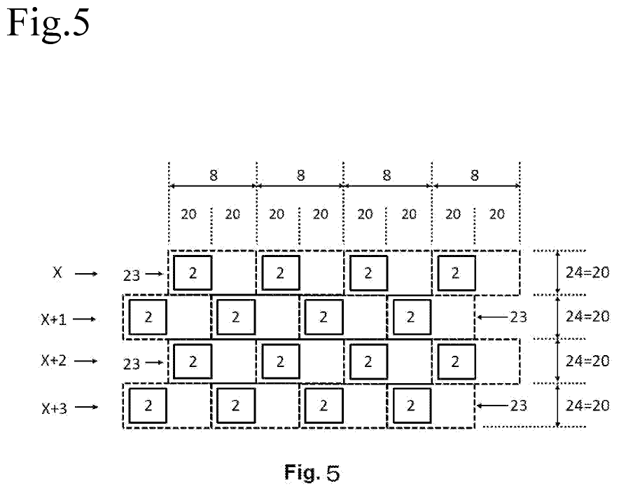

FIG. 5 shows a pixel arrangement in which rectangular pixels having a vertical pixel dimension of ½ of a horizontal pixel dimension are moved in the horizontal direction every other row by a shift dimension of ½ of the horizontal pixel dimension.

FIG. 5 is a diagram in which the high-resolution pixels 23 of FIG. 4 are arranged in the same manner as in FIG. 1, but only the light receiving units 2 are shown in the high-resolution pixels 23.

The arrangement of the high-resolution pixels 23 of the X row and the (X+2) row is an arrangement in which the high-resolution pixels 23 of the (X+1) row and the (X+3) row are moved in the row direction by the horizontal resolution dimension 20 which is ½ of the horizontal pixel dimension 8.

For the high-resolution pixels 23 of FIG. 4, since the vertical pixel dimension 24 is ½ of the horizontal pixel dimension 8, the horizontal resolution dimension 20 of the high-resolution pixels 23 of the X row and the (X+2) row can be made equal to the vertical pixel dimension 24 in FIG. 5.

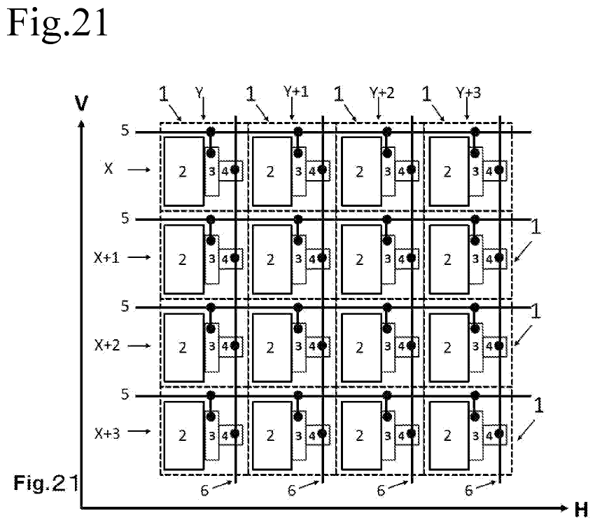

Therefore, since the horizontal resolution dimension 20 and the vertical resolution dimension 24 are the same, both the vertical and horizontal resolutions can be improved to respectively double both the vertical and horizontal resolutions of the conventional imaging device of FIG. 21.

As described above, in FIG. 5, the horizontal resolution and the vertical resolution can be improved at the same time, and miniaturization and high resolution of the CMOS image sensor can be realized.

Further, in FIG. 5, similarly to FIG. 1, since the high-resolution pixels 23 are only shifted in the horizontal direction, the drive wiring 5 of the high-resolution pixels 23 shown in FIG. 4 is not largely bent as in the staggered arrangement of FIG. 24. Therefore, high-speed driving of the drive wiring 5 can be realized.

Although each shift dimension of FIGS. 1, 3, and 5 is ½ of the horizontal pixel dimension 8, the shift dimension can improve the horizontal resolution when a movement of less than the horizontal pixel dimension 8 is performed. When the shift dimension is ½ of the horizontal pixel dimension 8, the horizontal resolution dimension 20 can be made the same, which is an ideal arrangement.

As described above, FIG. 1, FIG. 2, FIG. 3, FIG. 4, and FIG. 5 show the configuration using the same pixel 1 as the conventional CMOS image sensor of FIG. 20.

In particular, when the pixel 12 based on global shutter in which the honeycomb arrangement cannot be realized and the ToF pixel having a plurality of signal holding units 14 are configured in the same manner as in FIGS. 1, 2, 3, 4, and 5, there is a remarkable effect in terms of the speed increase of the drive wiring 5 and the miniaturization and high resolution of the CMOS image sensor.

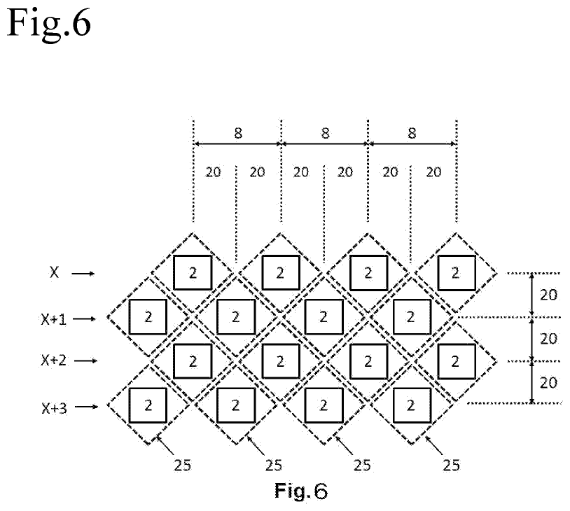

FIG. 6 shows a pixel arrangement in which micro-lenses are formed on a rectangular pixel having a vertical pixel dimension of ½ of a horizontal pixel dimension and the micro-lenses are arranged in a staggered manner.

By using the pixel arrangement as shown in FIG. 5, it is possible to arrange the micro-lenses 25 in a staggered manner around the center of gravity of the area of the light receiving unit 2. By adopting the staggered arrangement of the micro-lenses 25 in this way, it is possible to most efficiently collect light in a region other than the light receiving unit shown in FIG. 5, and to realize high sensitivity.

In the case of FIG. 5, the staggered micro-lenses 25 are obtained by rotating a quadrangle by 45 degrees, and in FIG. 1 and FIG. 3 as well, by arranging the rhombic micro-lenses in a staggered manner, high sensitivity can be similarly realized.

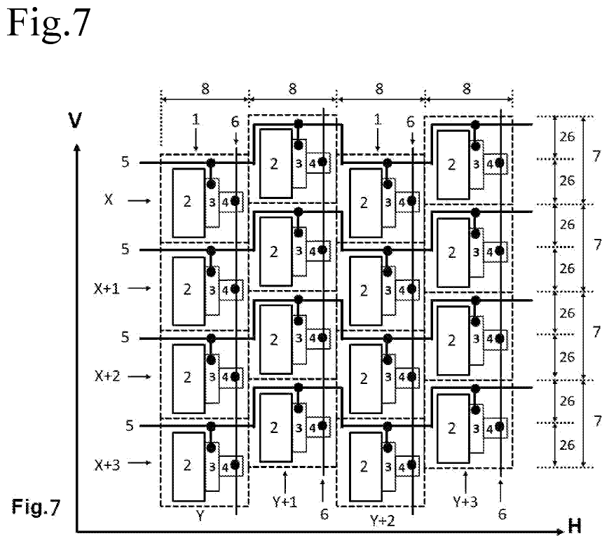

FIG. 7 shows a pixel arrangement in which pixels whose horizontal pixel dimension and vertical pixel dimension are the same are arranged by being moved in a vertical direction every other column by a shift dimension of ½ of the vertical pixel dimension.

FIG. 7 is a diagram in which the pixels 1 of FIG. 20 are moved every other column by a shift dimension of ½ of the vertical pixel dimension 7, and shows a pixel arrangement in which the vertical resolution is improved as compared with FIG. 20.

The arrangement of the pixels of the (Y+1) column and the (Y+3) column is an arrangement in which the pixels of the Y column and the (Y+2) column are moved in the row direction by the shift dimension of ½ of the vertical pixel dimension 7.

In this case, in the vertical direction of the light receiving unit 2, the vertical resolution dimension 26 is ½ of the vertical pixel dimension 7, and thus, the vertical resolution has doubled as compared to the prior art.

Since the light receiving units 2 in the horizontal direction are repeated with the same horizontal pixel dimension 8 as in FIG. 20, the horizontal resolution of FIG. 1 is the same as in FIG. 20.

In FIG. 7, when the pixel 1 is shifted only in the vertical direction, the drive wiring 5 of the pixel 1 is largely bent as in the staggered arrangement of FIG. 24, and thus, it is difficult to realize high-speed driving of the drive wiring 5.

As described above, by moving the pixels 1 every other column in the vertical direction by the shift dimension that is ½ of the vertical pixel dimension 7, the vertical resolution can be increased, however, since the drive wiring 5 is greatly bent, there remains a problem that high-speed driving is disadvantageous. Therefore, when the pixels 1 are moved in the vertical direction every other column by the shift dimension of ½ of the vertical pixel dimension 7, some contrivance is required.

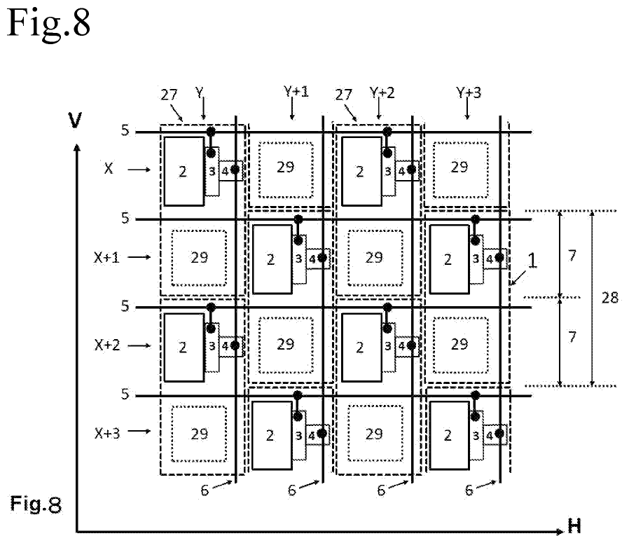

FIG. 8 shows a pixel arrangement in which rectangular pixels whose vertical pixel dimension is longer than horizontal pixel dimension are arranged by being moved in a vertical direction every other column by a shift dimension of ½ of the vertical pixel dimension.

In FIG. 7, the drive wiring 5 is largely bent and it is difficult to increase the speed, and thus in FIG. 8, the drive wiring 5 in the horizontal direction is made substantially linear and the distance of the drive wiring 5 is shortened to enable high-speed driving.

However, the vertically long rectangular pixel 27 of FIG. 8 is a rectangular pixel that is twice as long as the pixel 1 of FIG. 7 in the vertical direction. Thus, the vertical pixel dimension 28 of the vertically long rectangular pixel 27 is twice the vertical pixel dimension 7 of FIG. 7.

As a result, as an adverse effect caused by making the drive wiring 5 in the horizontal direction substantially linear, in the vertically long rectangular pixel 27, an invalid region 29 where nothing is arranged is formed, and therefore, the vertically long rectangular pixel 27 has an area twice as large as that of the pixel 1 of FIG. 7, and it is difficult to miniaturize the CMOS image sensor and to increase the resolution of the CMOS image sensor.

Therefore, in the configuration of FIG. 8, although the drive wiring 5 is substantially linear and high-speed driving is possible, the pixel area becomes large, and miniaturization and high resolution of the CMOS image sensor cannot be achieved.

As described above, as shown in FIGS. 7 and 8, in the state of the same pixel configuration as that of the conventional pixel 1, in the arrangement in which the pixels are moved every other column in the vertical direction by the shift dimension of ½ of the vertical pixel dimension,

it is difficult to achieve both the speed increase of the drive wiring 5 and the miniaturization and high resolution of the CMOS image sensor.

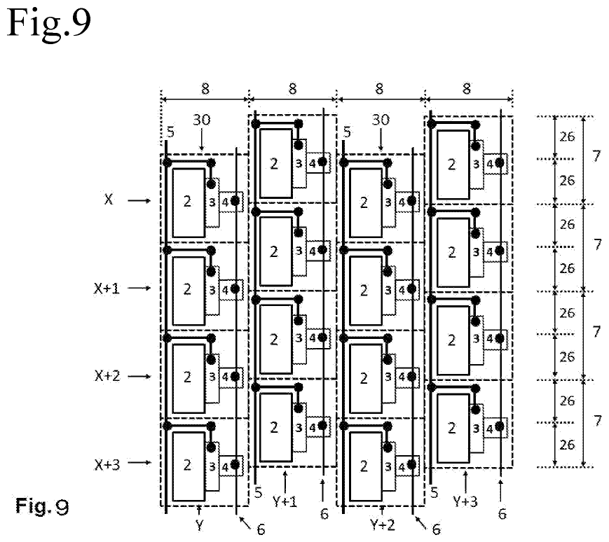

FIG. 9 shows a pixel arrangement in which pixels whose drive wirings are arranged in a vertical direction are arranged by being moved in the vertical direction every other column by a shift dimension of ½ of a vertical pixel dimension.

In FIG. 9, in the vertical wiring pixel 30, since the drive wiring 5 is arranged in the vertical direction, the drive wiring 5 is substantially in a straight line, and it is possible to increase the speed of the drive wiring 5. Further, since ½ of the vertical pixel dimension 7 is realized, the vertical resolution is doubled, and the CMOS image sensor can be miniaturized and increased in resolution.

Therefore, in the case of the pixel arrangement in which the vertical wiring pixels 30 are arranged by being moved in the vertical direction by the shift dimension of ½ of the vertical pixel dimension 7, the drive wiring 5 is arranged in parallel with the direction in which the vertical wiring pixels 30 are shifted, and thus, it is possible to achieve both the speed increase of the drive wiring 5 and the miniaturization and high resolution of the CMOS image sensor.

Further, the horizontal resolution of FIG. 9 can be improved by shortening the horizontal pixel dimension 8 of the vertical wiring pixel 30 of FIG. 9 to form a rectangular pixel. This is a pixel structure similar to the pixel structure obtained by rotating the pixel of FIG. 2 by 90 degrees.

Further, by making the vertical wiring pixel 30 of FIG. 9 a rectangular pixel in which the horizontal pixel dimension 8 is ½ of the vertical pixel dimension 7, the horizontal resolution of FIG. 9 can be made the same as the vertical resolution 26. This is a pixel structure similar to the pixel structure obtained by rotating the pixel of FIG. 4 by 90 degrees.

In addition, when a CMOS image sensor having a large horizontal ratio such as the aspect ratio of horizontal:vertical=12:5 of the movie image of FIG. 26-3 is manufactured using the arrangement method of FIG. 9, it is possible to simultaneously realize high horizontal resolution and high-speed driving of the drive wiring 5.

As described above, FIG. 9 shows the configuration using the same pixel 1 as the conventional CMOS image sensor of FIG. 20.

In particular, when the pixel 12 based on global shutter in which the honeycomb arrangement cannot be realized or the ToF pixel having a plurality of signal holding units 14 is configured in the same manner as in FIG. 9, there is a remarkable effect in terms of the speed increase of the drive wiring 5 and the miniaturization and high resolution of the CMOS image sensor.

From the above results, when FIG. 1 and FIG. 9 are compared, FIG. 9 is very similar to the pixel arrangement obtained by rotating FIG. 1 by 90 degrees. The pixel arrangement obtained by rotating FIG. 1 by 90 degrees differs from FIG. 9 only in that the vertical signal line 6 is different by 90 degrees.

In particular, an important common point is that the direction in which the pixels are shifted is parallel to the wiring direction of the drive wiring 5.

In FIG. 1, the pixel shift is in the horizontal direction, and the wiring direction of the drive wiring 5 is also in the horizontal direction.

In FIG. 9, the pixel shift is in the vertical direction, and the wiring direction of the drive wiring 5 is also in the vertical direction.

Therefore, even when FIG. 1 or FIG. 9 is rotated in a range of less than 360 degrees, when the condition that the direction in which the pixels are shifted and the wiring direction of the drive wiring 5 are parallel to each other is maintained, it is possible to achieve both the speed increase of the drive wiring 5 and the miniaturization and high resolution of the CMOS image sensor.

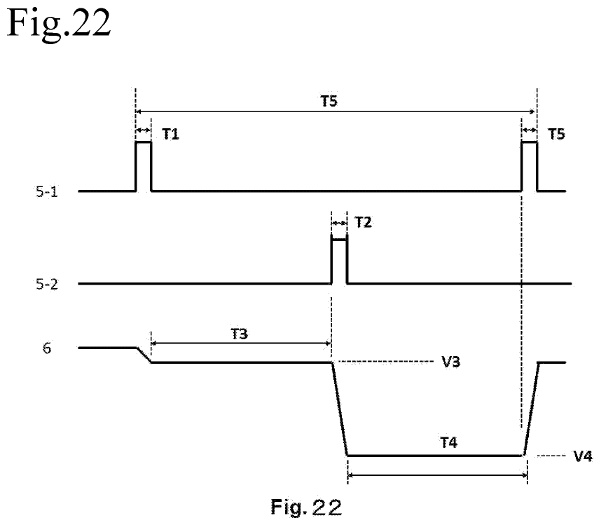

In the case of the structures shown in FIGS. 1, 3, 5, and 9, the time of the drive pulses T1, T5, and T2 shown in FIG. 22 needs to be about 0.5 microseconds to 5 microseconds in order to realize the speed increase.

Therefore, by setting the drive pulses T1, T5, and T2 to at least 5 microseconds or less, it is possible to increase the speed of the drive wiring 5 of the CMOS image sensor having the structures shown in FIGS. 1, 3, 5, and 9. A pulse is applied to the drive wiring 5 as shown in FIG. 22, and the same effect can also be obtained when a sine wave is applied.

Further, by adopting the staggered arrangement of the micro-lenses 25 used in FIG. 6 on the light receiving unit 2 of FIG. 9, it is possible to realize the high sensitivity of the CMOS image sensor as in the case of adopting the arrangement in FIG. 5.

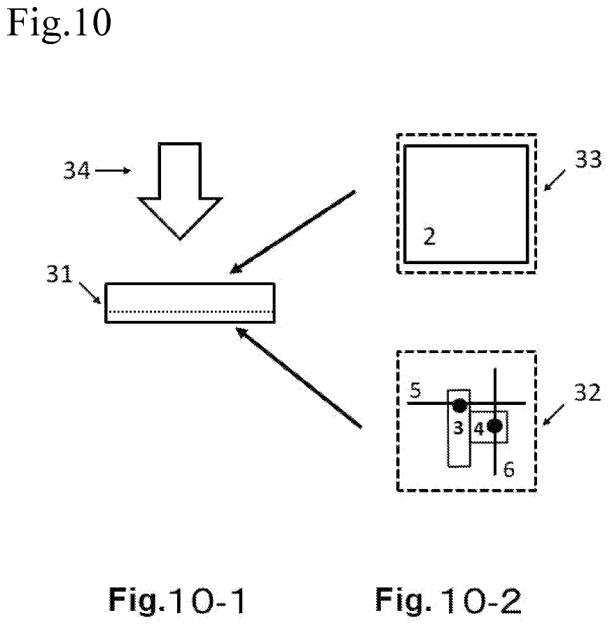

FIG. 10-1 shows a side view of a back side illumination type pixel.

FIG. 10-2 shows top and bottom views of the back side illumination type pixel.

In FIG. 10-1, when viewed from a side surface of the back side illumination type pixel 31, the drive wiring 5 is formed in the surface circuit unit 32 on a surface side (lower side) of a semiconductor, and the back side light receiving unit 33 is formed on a back side (upper side) of the semiconductor.

In the back side illumination type pixel, the side on which a circuit such as the drive wiring 5 is formed is the “surface side”, which is the surface circuit unit 32 in FIG. 10-2. On the opposite side of the surface circuit unit 32, the side of the back side light receiving unit 33 on which the light receiving unit 2 is provided is the “back side”.

Since a light 34 is incident on the light receiving unit 2 of the back side light receiving unit 33, the pixel having this structure is referred to as a “back side illumination type” or “Back Side Illumination (BSI) Type” pixel.

According to this structure, the drive wiring 5 of the surface circuit unit 32 and the light receiving unit 2 of the back side light receiving unit 33 can be designed independently to some extent.

Similarly to FIG. 1, since it is necessary to read the signal of the light receiving unit 2 from the reading unit 3, there is some restriction in design. First, the reading unit 3 of the surface circuit unit 32 and the light receiving unit 2 of the back side light receiving unit 33 are vertically connected to each other in the back side illumination type pixel 31.

Basically, both the pixel size of the surface circuit unit 32 and the pixel size of the back side light receiving unit 33 are the same as the size of the back side illumination type pixel 31.

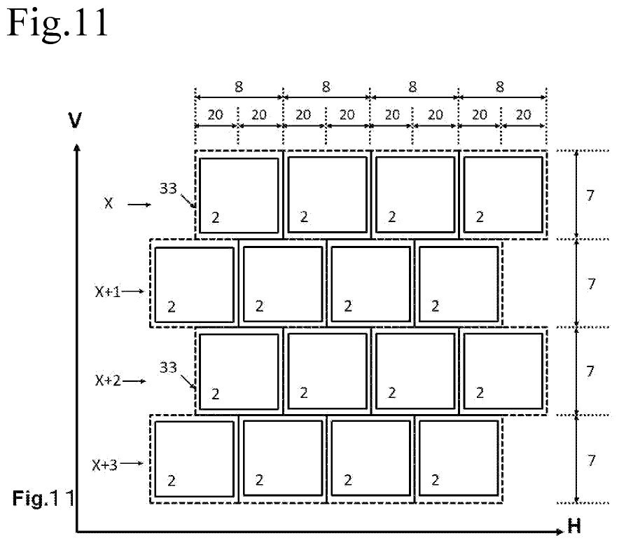

FIG. 11 shows a pixel arrangement in which, in a back side illumination type pixel, back side light receiving units are arranged by being moved in a horizontal direction every other row by a shift dimension of ½ of a horizontal pixel dimension.

In FIG. 11, the light receiving units 2 of the back side light receiving units 33 are simply arranged. In FIG. 11, similarly to FIG. 1, the light receiving units 2 of the X row and the (X+2) row are arranged in a manner of moving the light receiving units 2 of the (X+1) row and the (X+3) row in the horizontal direction by the shift dimension of ½ of the horizontal pixel dimension 8.

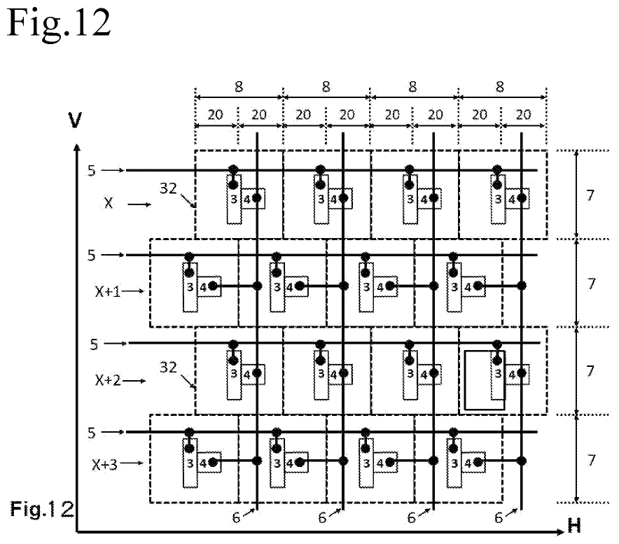

FIG. 12 shows a pixel arrangement in which, in a back side illumination type pixel, surface circuit units are arranged by being moved in a horizontal direction every other row by a shift dimension of ½ of a horizontal pixel dimension.

In FIG. 12, similarly to FIG. 1, the reading units 3 and the output units 4 of the X row and the (X+2) row are arranged by moving the reading units 3 and the output units 4 of the surface circuit units 32 of the (X+1) row and the (X+3) row in the horizontal direction by the shift dimension of ½ of the horizontal pixel dimension 8.

In FIG. 1, since the drive wiring 5 and the vertical signal line 6 are formed on the same plane as the light receiving unit 2, the drive wiring 5 and the vertical signal line 6 must be wirings avoiding the light receiving unit 2 in a manner of not overlapping the light receiving unit 2. For this reason, in FIG. 1, the vertical signal line 6 is a wiring that is bent in an uneven manner.

Basically, the frequency of the vertical signal line 6 is lower than the frequency of the drive wiring 5, and there are many cases where no problem arises in the operation of the CMOS image sensor when the vertical signal line 6 is bent in an uneven manner. However, when a high-speed subject such as a bullet is photographed, the number of frames of the image becomes high, and the vertical signal line 6 may also be driven at high speed in proportion to the number of frames, and thus, eliminating the uneven wiring is advantageous for speed increase.

In the case of FIG. 12, since the drive wiring 5 and the vertical signal line 6 are less likely to be affected by the light receiving unit 2, both the drive wiring 5 and the vertical signal line 6 can be wired in a straight line, and thus, high-speed wiring of both can be realized.

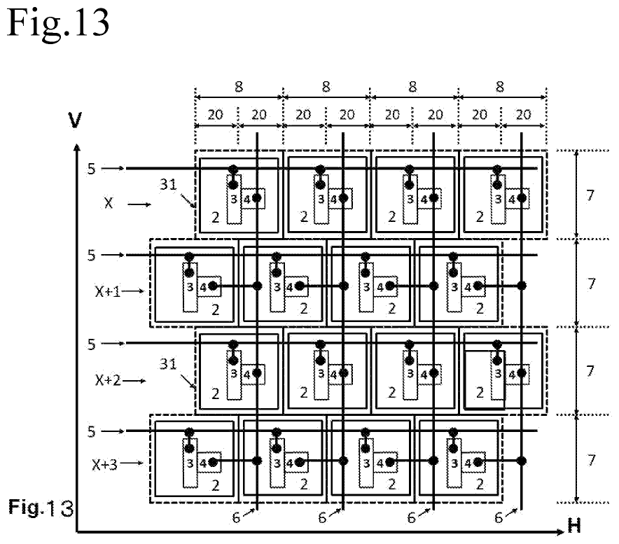

FIG. 13 shows a pixel arrangement in which back side illumination type pixels are arranged by being moved in a horizontal direction every other row by a shift dimension of ½ of a horizontal pixel dimension.

FIG. 13 is a diagram in which FIG. 11 and FIG. 12 are overlapped. Although the light receiving unit 2, the reading unit 3, the output unit 4, the drive wiring 5, and the vertical signal line 6 overlap each other in the drawing, since the light receiving unit 2 is arranged in the back side light receiving unit 33 and the reading unit 3, the output unit 4, the drive wiring 5, and the vertical signal line 6 are arranged in the surface circuit unit 32, they can be designed in a manner of not being affected by each other.

FIG. 13 shows that similarly to FIG. 1, the horizontal pixel dimension 8 and the vertical pixel dimension 7 are the same pixel dimension, and similarly to FIG. 1, the speed increase of the drive wiring 5 can be realized, and the high horizontal resolution of the CMOS image sensor can be realized because the horizontal resolution dimension 20 is as small as ½ of the horizontal pixel dimension 8.

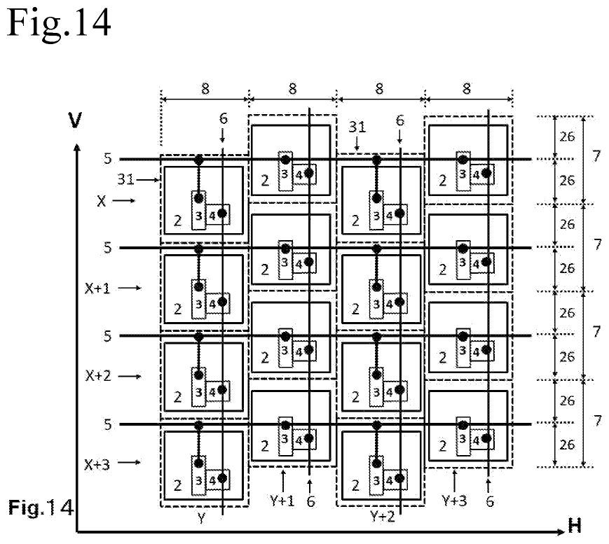

FIG. 14 shows a pixel arrangement in which back side illumination type pixels are arranged by being moved in a vertical direction every other column by a shift dimension of ½ of a vertical pixel dimension. In FIG. 7, when the conventional pixels are simply moved in the vertical direction every other column by the shift dimension of ½ of the vertical pixel dimension, the drive wiring 5 is greatly bent, and thus, it is difficult to increase the speed.

However, as described with reference to FIG. 13, since the light receiving unit 2 is arranged in the back side light receiving unit 33 and the reading unit 3, the output unit 4, the drive wiring 5, and the vertical signal line 6 are arranged in the surface circuit unit 32, they can be designed in a manner of not being affected by each other, and thus, it is also possible to design the back side illumination type pixels 31 similarly in the case of FIG. 14.

Therefore, when the back side illumination type pixels 31 are used, in the pixel arrangement in which the pixels are arranged by being moved in the vertical direction every other column by the shift dimension of ½ of the vertical pixel dimension, the drive wiring 5 arranged in the surface circuit unit 32 can be formed without being largely bent, and thus the speed increase of the drive wiring 5 can be realized. Further, since the vertical resolution dimension 26 is as small as ½ of the vertical pixel dimension 7, the high resolution of the CMOS image sensor can be realized.

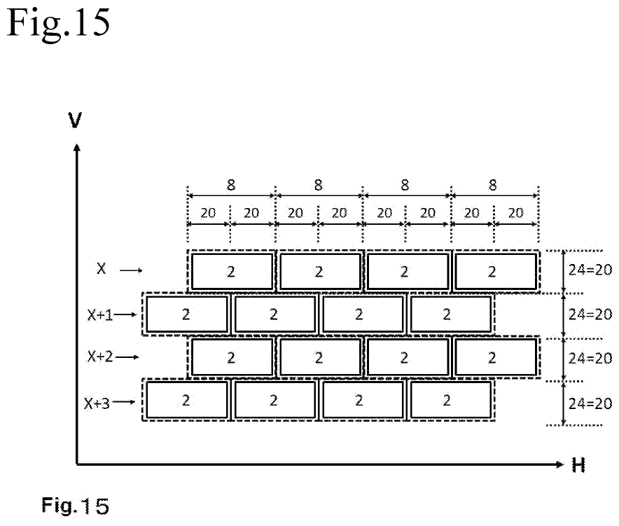

FIG. 15 shows a pixel arrangement in which back side light receiving units of back side illumination type pixels whose vertical pixel dimension is smaller than horizontal pixel dimension are arranged by being moved in the horizontal direction every other row by a shift dimension of ½ of the horizontal pixel dimension. Similarly to FIG. 5, the back side light receiving unit 33 is an example of a pixel in which the horizontal resolution dimension 20 and the vertical resolution dimension 24 are the same, and the vertical pixel dimension: the horizontal pixel dimension=1:2.

In this case, FIG. 15 realizes a high resolution in which both the horizontal resolution and the vertical resolution are doubled with respect to the conventional pixel arrangement shown in FIG. 21.

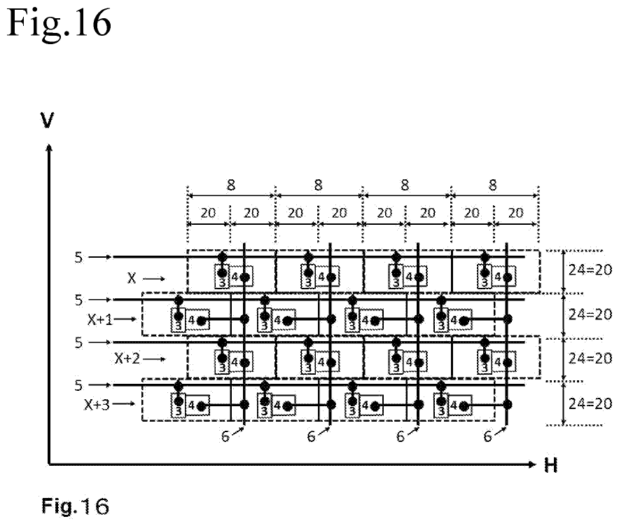

FIG. 16 shows a pixel arrangement in which surface circuit units of back side illumination type pixels whose vertical pixel dimension is smaller than horizontal pixel dimension are arranged by being moved in the horizontal direction every other row by a shift dimension of ½ of the horizontal pixel dimension. The drive wiring 5 and the vertical signal line 6 arranged in the surface circuit unit 32 can be formed in a straight line without being affected by the back side light receiving unit 33.

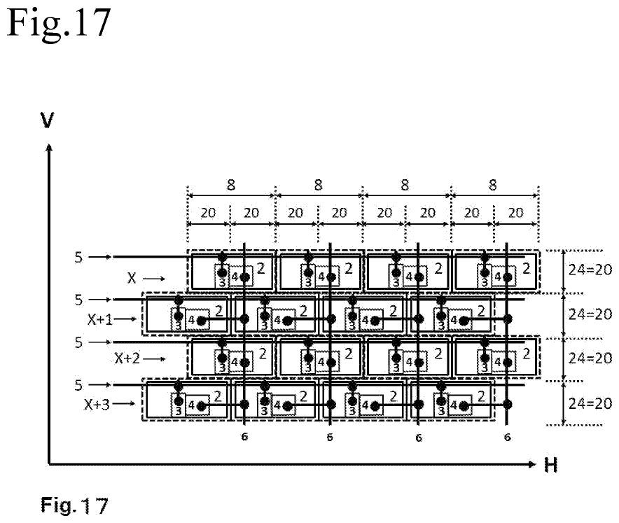

FIG. 17 shows a pixel arrangement in which back side illumination type pixels which have surface circuit units and back side light receiving units and have a vertical pixel dimension which is smaller than a horizontal pixel dimension are arranged by being moved in the horizontal direction every other row by a shift dimension of ½ of the horizontal pixel dimension.

FIG. 17 is a diagram in which FIG. 15 and FIG. 16 are overlapped. Although the light receiving unit 2, the reading unit 3, the output unit 4, the drive wiring 5, and the vertical signal line 6 overlap each other in the drawing, since the light receiving unit 2 is arranged in the back side light receiving unit 33 and the reading unit 3, the output unit 4, the drive wiring 5, and the vertical signal line 6 are arranged in the surface circuit unit 32, they can be designed in a manner of not being affected by each other. A point to note in designing is to consider a configuration in which the signal of the light receiving unit 2 can be completely read via the connecting unit of the light receiving unit 2 and the reading unit 3.

In FIG. 17, it is possible to increase the speed of the vertical signal line 6 in addition to the drive wiring 5, and the horizontal resolution and the vertical resolution are increased twice as high as the conventional pixel arrangement shown in FIG. 21.

FIG. 17 shows an example of vertical pixel dimension: horizontal pixel dimension=1:2, but by making the vertical pixel dimension smaller than the horizontal pixel dimension, the vertical resolution can be improved as compared with FIG. 13.

Although FIGS. 13 and 17 show the case where the back side illumination type pixels are shifted in the horizontal direction, when the back side illumination type pixels are shifted in the vertical direction, the horizontal resolution and the vertical resolution can also be increased.

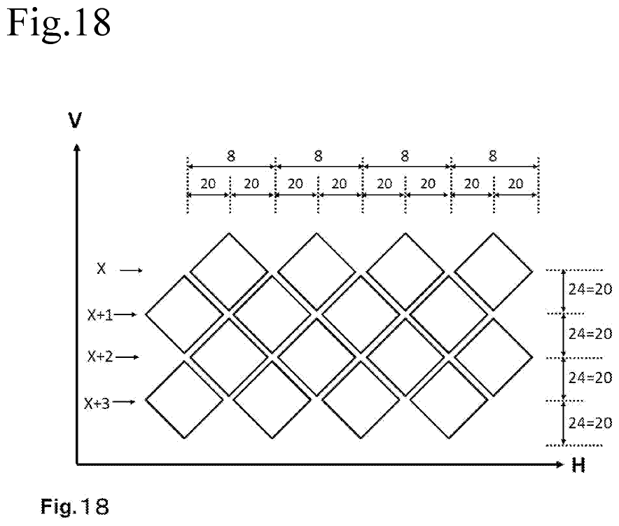

FIG. 18 is a back side illumination type pixel arrangement diagram in which back side light receiving units are arranged in a staggered manner.

As described with reference to FIGS. 14 and 17, it is possible to design the light receiving unit 2 arranged in the back side light receiving unit 33 and the reading unit 3, the output unit 4, the drive wiring 5, and the vertical signal line 6 arranged in the surface circuit unit 32 in a manner of not being affected by each other. Therefore, the back side light receiving unit 33 can be independently designed.

In the back side light receiving unit 33 of FIG. 15, the vertical pixel dimension: the horizontal pixel dimension=1:2, and the vertical pixel dimension is small, and thus, as pixels become smaller, vertical design becomes more difficult because the vertical pixel dimension is relatively small. In particular, as the vertical pixel dimension becomes finer, there is a possibility that it becomes difficult for light having a long wavelength to enter and it becomes difficult to achieve high sensitivity due to the vertical pixel dimension.

Therefore, the back side light receiving unit 33 is improved to have a shape similar to a square as shown in FIG. 18 and is arranged in a staggered manner to realize high sensitivity, and is combined with the surface circuit unit 32, and consequently, it is possible to realize the miniaturization and high resolution of the pixels together.

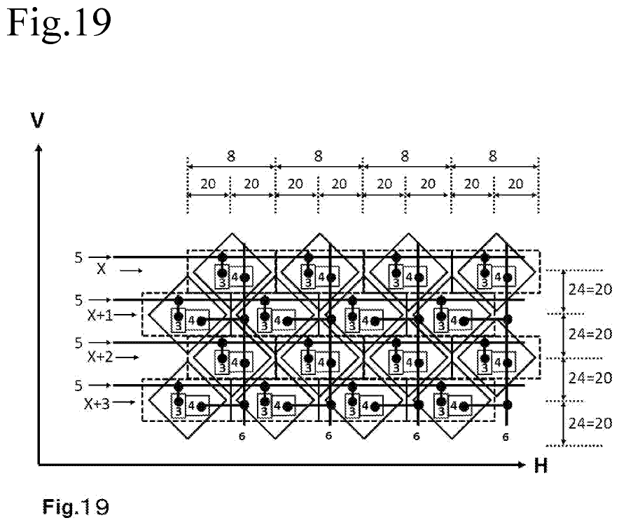

FIG. 19 is a back side illumination type pixel arrangement diagram in which a rectangular surface circuit unit and a back side light receiving unit with a staggered arrangement are overlapped with each other.

FIG. 19 shows a back side illumination type pixel 31 having a configuration in which the rectangular surface circuit unit 32 shown in FIG. 16 and the back side light receiving unit 33 arranged in a staggered manner shown in FIG. 18 overlap each other, and the surface circuit unit 32 and the back side light receiving unit 33 can be designed independently with a certain degree of freedom as in FIG. 17.

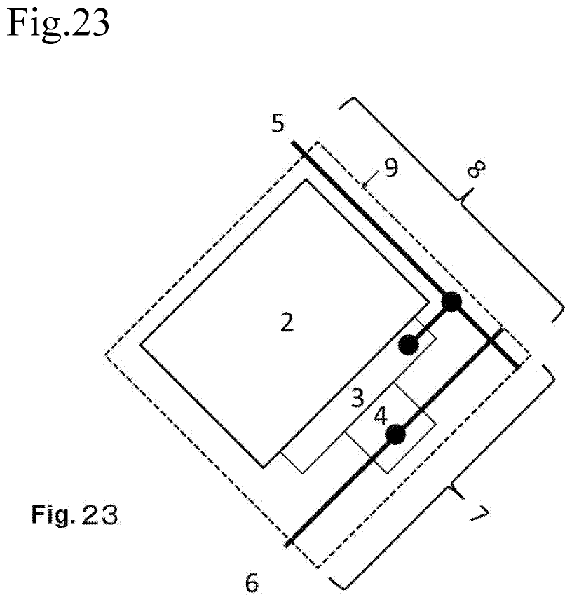

When the back side illumination type pixels 31 of FIG. 10-1 are arranged in a staggered manner, both the surface circuit unit 32 and the back side light receiving unit 33 of FIG. 10-2 are rotated by 45 degrees, and thus, the drive wiring 5 is greatly bent as in the case where the conventional pixel 1 shown in FIGS. 23 and 24 is rotated by 45 degrees, and thus, it is difficult to increase the speed of the drive wiring 5.

On the other hand, in FIG. 19, the drive wiring 5 can be arranged in a straight line by rotating only the back side light receiving units 33 by 45 degrees without rotating the surface circuit units 32 and arranging the back side light receiving units 33 in a staggered manner.

As described above, by realizing the back side illumination type pixel arrangement in which the rectangular surface circuit unit 32 and the back side light receiving unit 33 having the staggered arrangement overlap each other, it is possible to realize the speed increase of the drive wiring 5 and the vertical signal line 6, the miniaturization, the high resolution, and the high sensitivity of the pixel at the same time, and there is a remarkable performance improvement effect which is greater than the effect of FIG. 17.

Although FIG. 19 shows an example in which the surface circuit unit 32 has a rectangular shape, the boundary region of the surface circuit unit 32 of the pixel may have a trapezoidal shape, a rhombic shape, or a curved shape instead of a rectangular shape.

If the surface circuit unit 32 has a shape in which the drive wiring 5 can be arranged in a straight line as much as possible and can be arranged in a shift arrangement every other row, the same performance improvement effect can be obtained.

FIGS. 1, 3, 5, 9, 13, 14, 15, and 17 show that like in FIG. 19, as long as the shape of the boundary region of the pixel is such that the drive wiring 5 can be arranged in a straight line and speed increase can be realized, even if the shape of the boundary region is a trapezoid, a rhombus, or a curved line instead of a quadrangle, the respective effects of FIGS. 1, 3, 5, 9, 13, 15, and 17 can be obtained.

In FIGS. 1, 3, 5, 9, 13, 14, 15, 17 and 19, the drive wiring 5 is connected in a straight line, but some distortion is allowable.

Basically, when the drive wiring 5 and the another drive wiring 5 of the adjacent pixel are connected to each other, the drive wirings are designed to be as parallel as possible with respect to the direction in which the drive wirings 5 are connected, so that the speed increase can be realized.

FIGS. 13, 14, 15, 17, and 19 show that when the CMOS image sensor having the back side illumination type pixel 31 is rotated in a range of less than 360 degrees, it is also possible to realize the speed increase of the drive wiring 5 and the vertical signal line 6, and the miniaturization, high resolution and high sensitivity of the pixel.

In FIGS. 1, 3, 5, and 9, by setting T1 and T5 of the reset pulse (5-1) and T2 of the read pulse (5-2) of FIGS. 22 to 5 microseconds or less, the speed increase of the drive wiring 5 of the CMOS image sensor has been realized, and FIGS. 13, 14, 15, 17, and 19 show that even for the CMOS image sensor having the back side illumination type pixels 31, T1, T5, and T2 of FIG. 22 can be reduced to 5 microseconds or less to realize the speed increase of the drive wiring 5 of the CMOS image sensor. T1, T5, and T2 have similar effects when they are not pulses but sine waves of 5 microseconds or less.

Further, by adopting the staggered arrangement of the micro-lenses 25 used in FIG. 6 on the light receiving unit 2 of the back side illumination type pixel 31 of FIGS. 13, 14, 15, 17 and 19, it is possible to realize the high sensitivity of the CMOS image sensor as in the case of adopting the arrangement in FIGS. 1, 3 and 5.

For the back side illumination type pixel 31 of FIGS. 13, 14, 15, 17 and 19, particularly, by adopting the pixel 12 based on global shutter in which the honeycomb arrangement cannot be realized and the ToF pixel having a plurality of signal holding units 14, a remarkable effect can be obtained in terms of the speed increase of the drive wiring 5 and vertical signal line as well as the miniaturization, high resolution and high sensitivity of the CMOS image sensor.

The embodiment of the present invention are not limited to the embodiment described above, and can be implemented in various forms including the contents of the present invention.

Although the embodiment of the present invention have been described on CMOS image sensor, the present invention can also be implemented in various forms including the contents of the present invention in a sensor other than CMOS image sensor.

### INDUSTRIAL APPLICABILITY

An electronic apparatus equipped with the imaging device according to the present invention is used in many fields such as a mobile phone, a camera for industrial equipment, a medical camera, and a vehicle-mounted camera.

### DESCRIPTION OF REFERENCE SIGNS

1: Pixel

2: Light receiving unit

3: Reading unit

4: Output unit

5: Drive wiring

6: Vertical signal line

7: Vertical pixel dimension

8: Horizontal pixel dimension

9: Rotation pixel

10: Horizontal resolution

11: Vertical resolution

12: Global shutter pixel

13: Transfer unit

14: Signal holding unit

15: Reading unit wiring

16: Signal holding unit wiring

17: Television image

18: High-resolution television image

19: Movie image

20: Horizontal resolution dimension

21: Horizontally long rectangular pixel

22: Vertical pixel dimension

23: High-resolution pixel

24: Vertical pixel dimension

25: Micro-lens

26: Vertical resolution dimension

27: Vertically long rectangular pixel

28: Vertical pixel dimension

29: Invalid region

30: Vertical wiring pixel

31: Back side illumination type pixel

32: Surface circuit unit

33: Back side light receiving unit

34: Light

1. An imaging device having pixels, each of the pixels comprising:
a light receiving unit that photoelectrically converts an incident light to generate a signal charge;
an output unit that detects the signal charge of the light receiving unit; and
a drive wiring that operates the output unit,
the imaging device being characterized in that
in an imaging region where the pixels are periodically arranged in a matrix
at a pitch of a horizontal pixel dimension in a row direction and
at a pitch of a vertical pixel dimension in a column direction,
an arrangement of the pixels in an X row and an (X+2) row is an arrangement in which the pixels in an (X+1) row and an (X+3) row are moved in the row direction by a shift dimension smaller than the horizontal pixel dimension, or
an arrangement of the pixels in a Y column and a (Y+2) column is an arrangement in which the pixels in a (Y+1) column and a (Y+3) column are moved in the column direction by a shift dimension smaller than the vertical pixel dimension.

2. The imaging device according to claim 1, characterized in that
when the arrangement of the pixels in the X row and the (X+2) row is the arrangement in which the pixels in the (X+1) row and the (X+3) row are moved in the row direction by the shift dimension smaller than the horizontal pixel dimension,
the drive wiring of the pixel and the drive wiring of the adjacent pixel have at least one wiring connected horizontally in a same row, or
when the arrangement of the pixels in the Y column and the (Y+2) column is the arrangement in which the pixels in the (Y+1) column and the (Y+3) column are moved in the column direction by the shift dimension smaller than the vertical pixel dimension,
the drive wiring of the pixel and the drive wiring of an adjacent pixel have at least one wiring connected vertically in a same column.

3. The imaging device according to claim 1, characterized in that
a signal line for outputting a signal from the output unit of the pixel
and the signal line of the pixel adjacent in the column direction
are connected in the column direction.

4. An imaging device characterized in that the imaging region according to claim 1 is rotated and arranged within a range of less than 360 degrees.

5. An imaging device characterized in that the imaging region according to claim 2 is rotated and arranged within a range of less than 360 degrees.

6. The imaging device according to claim 1, characterized in that
when the arrangement of the pixels in the X row and the (X+2) row is the arrangement in which the pixels in the (X+1) row and the (X+3) row are moved in the row direction by the shift dimension smaller than the horizontal pixel dimension,
the shift dimension is ½ of the horizontal pixel dimension, or
when the arrangement of the pixels in the Y column and the (Y+2) column is the arrangement in which the pixels in the (Y+1) column and the (Y+3) column are moved in the column direction by the shift dimension smaller than the vertical pixel dimension,
the shift dimension is ½ of the vertical pixel dimension.

7. The imaging device according to claim 1, characterized in that
when the arrangement of the pixels in the X row and the (X+2) row is the arrangement in which the pixels in the (X+1) row and the (X+3) row are moved in the row direction by the shift dimension smaller than the horizontal pixel dimension,
the vertical pixel dimension is smaller than the horizontal pixel dimension, or
when the arrangement of the pixels in the Y column and the (Y+2) column is the arrangement in which the pixels in the (Y+1) column and the (Y+3) column are moved in the column direction by the shift dimension smaller than the vertical pixel dimension,
the horizontal pixel dimension is smaller than the vertical pixel dimension.

8. The imaging device according to claim 1, characterized in that
when the arrangement of the pixels in the X row and the (X+2) row is the arrangement in which the pixels in the (X+1) row and the (X+3) row are moved in the row direction by the shift dimension smaller than the horizontal pixel dimension,
the vertical pixel dimension is ½ of the horizontal pixel dimension, or
when an arrangement of pixels in the Y column and the (Y+2) column is the arrangement in which pixels in the (Y+1) column and the (Y+3) column are moved in the column direction by the shift dimension smaller than the vertical pixel dimension,
the horizontal pixel dimension is ½ of the vertical pixel dimension.

9. The imaging device according to claim 1, characterized in that
a total row dimension of the pixels arranged in the row direction at the pitch of the horizontal pixel dimension is larger than a total column dimension of the pixels arranged in the column direction at the pitch of the vertical pixel dimension.

10. The imaging device according to claim 1, characterized in that
in the imaging region, micro-lenses having an area center of gravity are arranged in a staggered manner on the light receiving unit.

11. The imaging device according to claim 2, characterized in that
in the imaging region, micro-lenses having an area center of gravity are arranged in a staggered manner on the light receiving unit.

12. The imaging device according to claim 7, characterized in that
in the imaging region, micro-lenses having an area center of gravity are arranged in a staggered manner on the light receiving unit.

13. The imaging device according to claim 2, characterized in that
a voltage applied to the drive wiring has a pulse width of 5 microseconds or less or a sine wave of 5 microseconds or less.

14. The imaging device according to claim 1, characterized in that
the pixels are global shutter pixels having a signal holding unit for holding a signal of the light receiving unit, or
Time of Flight (ToF) pixels having a plurality of the signal holding units.

15. The imaging device according to claim 2, characterized in that
the pixels are global shutter pixels having a signal holding unit for holding a signal of the light receiving unit, or
Time of Flight (ToF) pixels having a plurality of the signal holding units.

16. The imaging device according to claim 7, characterized in that
the pixels are global shutter pixels having a signal holding unit for holding a signal of the light receiving unit, or
Time of Flight (ToF) pixels having a plurality of the signal holding units.

17. The imaging device according to claim 1, characterized in that
the pixel is a back side illumination type pixel in which the drive wiring is formed on a surface side of a semiconductor, and
the light receiving unit is formed on a back side of the semiconductor, and is thus a so-called Back Side Illumination (BSI) type pixel.

18. The imaging device according to claim 7, characterized in that
the pixel is a back side illumination type pixel in which the drive wiring is formed on a surface side of a semiconductor, and
the light receiving unit is formed on a back side of the semiconductor, and is thus a so-called Back Side Illumination (BSI) type pixel.

19. The imaging device according to claim 14, characterized in that
the pixel is a back side illumination type pixel in which the drive wiring is formed on a surface side of a semiconductor, and
the light receiving unit is formed on a back side of the semiconductor, and is thus a so-called Back Side Illumination (BSI) type pixel.

20. The imaging device according to claim 17, characterized in that
the light receiving units of the back side illumination type pixels are in a staggered arrangement.

21. The imaging device according to claim 18, characterized in that
the light receiving units of the back side illumination type pixels are in a staggered arrangement.

22. The imaging device according to claim 19, characterized in that
the light receiving units of the back side illumination type pixels are in a staggered arrangement.

23. The imaging device according to claim 20, characterized in that
in the back side illumination type pixel,
of surface circuit units in which the drive wiring is formed on the surface side of the semiconductor,
the arrangement of the surface circuit units of the X row and the (X+2) row is an arrangement in which the surface circuit units of the (X+1) row and the (X+3) row are moved in the row direction by the shift dimension smaller than the horizontal pixel dimension of the surface circuit units, or
the arrangement of the surface circuit units of the Y column and the (Y+2) column is an arrangement in which the surface circuit units of the (Y+1) column and the (Y+3) column are moved in the column direction by the shift dimension smaller than the vertical pixel dimension of the surface circuit units.

24. The imaging device according to claim 21, characterized in that
in the back side illumination type pixel,
of surface circuit units in which the drive wiring is formed on the surface side of the semiconductor,
the arrangement of the surface circuit units of the X row and the (X+2) row is an arrangement in which the surface circuit units of the (X+1) row and the (X+3) row are moved in the row direction by the shift dimension smaller than the horizontal pixel dimension of the surface circuit units, or
the arrangement of the surface circuit units of the Y column and the (Y+2) column is an arrangement in which the surface circuit units of the (Y+1) column and the (Y+3) column are moved in the column direction by the shift dimension smaller than the vertical pixel dimension of the surface circuit units.

25. The imaging device according to claim 22, characterized in that
in the back side illumination type pixel,
of surface circuit units in which the drive wiring is formed on the surface side of the semiconductor,
the arrangement of the surface circuit units of the X row and the (X+2) row is an arrangement in which the surface circuit units of the (X+1) row and the (X+3) row are moved in the row direction by the shift dimension smaller than the horizontal pixel dimension of the surface circuit units, or
the arrangement of the surface circuit units of the Y column and the (Y+2) column is an arrangement in which the surface circuit units of the (Y+1) column and the (Y+3) column are moved in the column direction by the shift dimension smaller than the vertical pixel dimension of the surface circuit units.
